(19) United States
(12) Patent Application Publication
(10) Pub. No.: US 2026/0173866 A1
(43) Pub. Date: Jun. 18, 2026

(54) TIM-FREE HEAT SPREADER

(71) Applicant: Board of Regents, The University of Texas System, Austin, TX (US)

(72) Inventors: Sidlgata V. Sreenivasan, Austin, TX (US); Li Shi, Austin, TX (US); Paras Ajay, Austin, TX (US); Vaibhav Bahadur, Austin, TX (US)

(21) Appl. No.: 19/126,503

(22) PCT Filed: Nov. 2, 2023
(86) PCT No.: PCT/US2023/036722

§ 371 Date: May 1, 2025

Related U.S. Application Data
(60) Provisional application No. 63/422,083, filed on Nov. 3, 2022.

(51) Int. Cl. H10W 40/22; F28D 21/00; H10W 40/00; H10W 40/20; H10W 40/25

(52) U.S. Cl. CPC H10W 40/22; H10W 40/03; H10W 40/033; H10W 40/233; H10W 40/253; F28D 2021/0028

(57) ABSTRACT

A heat spreader placed in connection with a heat generating device. The heat spreader includes patterned regions with interspersed bulk semiconductor and thermally conductive material. Furthermore, the heat spreader includes tapered structures that cause thermal conductivity and/or thermal expansion in the heat spreader to gradually change from that of the heat generating device to that of the thermally conductive material. In this manner, the design and performance of heat spreaders is improved by eliminating the need for utilizing the thermal interface material.

### TECHNICAL FIELD

The present invention relates generally to heat spreaders, and more particularly to a heat spreader without implementing a thermal interface material.

### BACKGROUND

Heat spreaders are objects with a high thermal conductivity that either connect a heat source to another heat exchanger or that release heat to ambient air to prevent the overheating of critical components. These heat-dissipating devices are typically made of copper, aluminum, graphite, or diamond. Different types of heat spreaders, including metallic heat spreaders; phase-change devices, such as heat pumps and vapor changers; and thermal transfer compounds to fill air gaps, have been designed to maximize heat transfer efficiency for different applications. Heat spreaders are commonly used in computer processors, mobile devices, and automotive electronics, among other things.

Heat spreaders are important devices for preventing the overheating of critical components in electronics and industrial systems. Overheating harms the performance of electronics in two ways: it degrades the performance of semiconductors, whose resistivity drops with increasing temperature as well as the performance of the metallic connections of the electronic components to the rest of the electronic system. This causes the hard drive and processor to slow down. If too much heat is developed without being dissipated, the excessive heat can cause computer systems to crash and damage components.

A heat spreader works by conducting thermal energy from a heat source to either a secondary heat exchanger or to a cooler medium. This can be accomplished using either solid pieces of materials with high thermal conductivity or by taking advantage of the absorption of heat required to change a material from one phase to another (usually liquid to vapor).

In solid heat spreaders, the heat is conducted through the metal block and away from the source. Phase change heat spreaders work by changing the state of matter of a volatile liquid or gas. The cool liquid changes into a vapor after contacting the hot, outer surface. This vapor then travels through a heat pipe or vapor chamber to a secondary heat exchanger to carry heat away from the source. The vapor then recondenses into a liquid and repeats the cycle.

Heat spreaders typically contain a base material, a thermal interface material, fins, heat pipes, fans, and an enclosure.

The base material forms the primary sheet, block, or gap-filling structure of a heat spreader that transfers heat from the higher-temperature source to the secondary heat exchanger. Base materials must have high thermal conductivity. As a result, copper, aluminum, graphite, and diamond are commonly used for the base materials.

The thermal interface material (TIM) is a substance placed between the heat spreader and the heat-generating device to help improve heat transfer. TIM is typically a silicone-based thermal grease or thermal paste with metal oxide, silver, or graphite fillers.

Fins are protrusions from the primary body of the heat spreader that enhance the amount of surface area available for conduction away from the heat source. Ambient air flows between the fins and further removes heat from the fins, and thus from the system, by convection. Fins are made from the same base material as the rest of the heat spreader.

Heat pipes are closed pipes consisting of a thermally conductive outer structure, a wick, and a working fluid. One end of the heat pipe lies in the zone that is to be cooled and absorbs heat from it. This heat evaporates the liquid in the wick, on the inside wall of the heat pipe. The resulting gas moves down the center of the pipe to the condenser section, where the cooler walls recondense the vapor in the wick. Capillary action then pulls that liquid back to the hot (evaporator) zone, providing a continuous circulation of cooling fluid within the sealed pipe.

Fans are typically placed at the end of the heat spreader. The fans help dissipate heat further due to forced convection.

Some electronics do not have space for heat spreader components. Therefore, large flat enclosures made from copper or aluminum are used to dissipate heat. Enclosures are typically used for electronics that operate in applications with excess vibration or in applications where electronics must be protected from the environment.

Unfortunately, the current design of heat spreaders includes several components as discussed above, including thermal interface material, making the design difficult to manufacture.

### SUMMARY

In one embodiment of the present disclosure, a heat spreader placed in connection with a heat generating device comprises patterned regions with interspersed bulk semiconductor and thermally conductive material. The heat spreader further comprises tapered structures that cause thermal conductivity in the heat spreader to gradually change from that of the heat generating device to that of the thermally conductive material.

In another embodiment of the present disclosure, a heat spreader placed in connection with a heat generating device comprises patterned regions with bulk semiconductor and thermally conductive material. An effective area of contact between the bulk semiconductor and the thermally conductive material exceeds 0.8 times that of a flat areal contact between a surface of an unpatterned bulk semiconductor and a surface of the thermally conductive material, where an effective thermal expansion coefficient of the heat spreader matches a thermal expansion of the heat generating device.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIGS. 1A-1C illustrate an exemplary architecture for a heat spreader in accordance with an embodiment of the present disclosure;

FIG. 2A illustrates a top view of the unit cells of the heat spreader in a 2×2 array in accordance with an embodiment of the present disclosure; and

FIGS. 2B-2C illustrate a cross-section of the unit cells of FIG. 2A in accordance with an embodiment of the present disclosure.

### DETAILED DESCRIPTION

As stated above, heat spreaders are important devices for preventing the overheating of critical components in electronics and industrial systems. Overheating harms the performance of electronics in two ways: it degrades the performance of semiconductors, whose resistivity drops with increasing temperature as well as the performance of the metallic connections of the electronic components to the rest of the electronic system. This causes the hard drive and processor to slow down. If too much heat is developed without being dissipated, the excessive heat can cause computer systems to crash and damage components.

A heat spreader works by conducting thermal energy from a heat source to either a secondary heat exchanger or to a cooler medium. This can be accomplished using either solid pieces of materials with high thermal conductivity or by taking advantage of the absorption of heat required to change a material from one phase to another (usually liquid to vapor).

In solid heat spreaders, the heat is conducted through the metal block and away from the source. Phase change heat spreaders work by changing the state of matter of a volatile liquid or gas. The cool liquid changes into a vapor after contacting the hot, outer surface. This vapor then travels through a heat pipe or vapor chamber to a secondary heat exchanger to carry heat away from the source. The vapor then recondenses into a liquid and repeats the cycle.

Heat spreaders typically contain a base material, a thermal interface material, fins, heat pipes, fans, and an enclosure.

The base material forms the primary sheet, block, or gap-filling structure of a heat spreader that transfers heat from the higher-temperature source to the secondary heat exchanger. Base materials must have high thermal conductivity. As a result, copper, aluminum, graphite, and diamond are commonly used for the base materials.

The thermal interface material (TIM) is a substance placed between the heat spreader and the heat-generating device to help improve heat transfer. TIM is typically a silicone-based thermal grease or thermal paste with metal oxide, silver, or graphite fillers.

Fins are protrusions from the primary body of the heat spreader that enhance the amount of surface area available for conduction away from the heat source. Ambient air flows between the fins and further removes heat from the fins, and thus from the system, by convection. Fins are made from the same base material as the rest of the heat spreader.

Heat pipes are closed pipes consisting of a thermally conductive outer structure, a wick, and a working fluid. One end of the heat pipe lies in the zone that is to be cooled and absorbs heat from it. This heat evaporates the liquid in the wick, on the inside wall of the heat pipe. The resulting gas moves down the center of the pipe to the condenser section, where the cooler walls recondense the vapor in the wick. Capillary action then pulls that liquid back to the hot (evaporator) zone, providing a continuous circulation of cooling fluid within the sealed pipe.

Fans are typically placed at the end of the heat spreader. The fans help dissipate heat further due to forced convection.

Some electronics do not have space for heat spreader components. Therefore, large flat enclosures made from copper or aluminum are used to dissipate heat. Enclosures are typically used for electronics that operate in applications with excess vibration or in applications where electronics must be protected from the environment.

Unfortunately, the current design of heat spreaders includes several components as discussed above, including thermal interface material, making the design difficult to manufacture.

Embodiments of the present disclosure provide the means for simplifying the design of heat spreaders while improving performance by eliminating the need for utilizing the thermal interface material as discussed below.

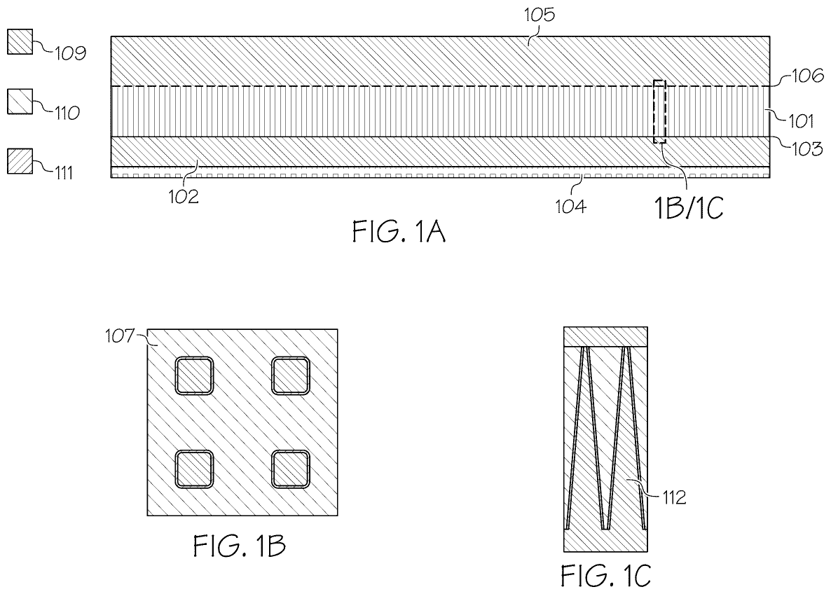

Referring now to the Figures in detail, FIGS. 1A-1C illustrate an exemplary architecture for a heat spreader in accordance with an embodiment of the present disclosure.

As illustrated in FIG. 1A, heat spreader 101 is placed adjacent or in connection with a heat generating device 102. In one embodiment, heat spreader 101 is TIM-free. That is, heat spreader 101 does not include thermal interface material.

In one embodiment, heat spreader 101 is comprised of tapered structures, such as silicon, and high-thermal conductivity material, such as copper, deposited in regions not occupied by the tapered structures using standard semiconductor fabrication processes for deposition (e.g., electroplating followed by chemical mechanical polishing (CMP)). In such an embodiment, the tapered structures cause thermal conductivity and/or thermal expansion in heat spreader 101 to gradually change from that of heat generating device 102 at one end of heat spreader 101 to that of the high-thermal conductivity material at the other end of heat spreader 101. In one embodiment, the effective thermal expansion coefficient of heat spreader 101 matches the thermal expansion of heat generating device 102.

In one embodiment, the thickness of heat spreader 101 is sub-1 μm, sub-2 μm, sub-5 μm, sub-10 μm. sub-20 μm, sub-50 μm, sub-100 μm, sub-250 μm, sub-500 μm, sub-1 mm, or sub-2 mm.

In one embodiment, the boundary between spreader 101 and device 102 includes an optional fusion bonded SiO₂—SiO₂ interface 103. Such an interface 103 may be utilized if heat spreader 101 is composed of silicon and a high-quality CVD material (e.g., c-BN, diamond, etc.).

In one embodiment, the thickness of device 102 is sub-1 μm, sub-2 μm, sub-5 μm, sub-10 μm. sub-20 μm, sub-50 μm, sub-100 μm, sub-250 μm, sub-500 μm, sub-1 mm, or sub-2 mm.

Furthermore, as illustrated in FIG. 1, device 102 includes circuit elements 104. In one embodiment, the lateral extent of circuit elements 104 is sub-1 mm, sub-2 mm, sub-5 mm, sub-10 mm, sub-15 mm, sub-50 mm, sub-100 mm, or sub-300 mm.

Additionally, as illustrated in FIG. 1, a bulk heat sink 105 resides on heat spreader 101. In one embodiment, bulk heat sink 105 is comprised of silicon. In one embodiment, the thickness of bulk heat sink 105 is sub-50 μm, sub-100 μm, sub-250 μm, sub-500 μm, sub-1 mm, or sub-2 mm.

In one embodiment, bulk heat sink 105 is attached to heat spreader 101 via an optional fusion-bonded SiO₂—SiO₂ interface 106. In one embodiment, the thickness of interface 106 is 5 nm.

Referring now to FIG. 1B, FIG. 1B illustrates a top view of the cross-section of heat spreader 101. As shown in FIG. 1B, heat spreader 101 is comprised of unit cells 107, where the lateral extent 108 of a unit cell 107 may have a lateral extent of sub-100 nm, sub-500 nm, sub-1 μm, sub-2 μm, sub-5 μm, sub-10 μm, sub-20 μm, sub-50 μm, sub-100 μm, sub-200 μm, or sub-500 μm. In one embodiment, heat spreader 101 is comprised of repeating unit cells 107.

In one embodiment, each cell 107 may be comprised of bulk semiconductor 109, such as silicon, high thermal conductivity material 110 (e.g., copper, BN, boron phosphide (BP), boron arsenide (BAs), aluminum nitride, diamond, carbon nanotubes (these materials could be deposited using one or more of the following techniques: (a) chemical vapor deposition (CVD), including MOCVD, LPCVD, APCVD, and hot-filament CVD, (b) atomic layer deposition (ALD), including plasma enhanced ALD, (c) sputtering, (d) e-beam deposition, (e) electroplating, each of which could be followed with high-temperature annealing, where “high-temperature” is over-700° C., over-800° C., over-900° C., or over-1000° C., and where the deposited material could be in mono-crystalline, poly-crystalline, amorphous, planar sheets, h-BN, nanowires, etc.), and optional electrically-insulating material 111 (e.g., SiO₂, tantalum oxide/nitride). Hence, heat spreader 101 includes patterned regions with interspersed bulk semiconductor 109 and high thermal conductive material 110. In one embodiment, each cell 107 is comprised of only high thermal conductivity material 110. Any bulk semiconductor 109, such as silicon, which might be present during the fabrication process, could be selectively removed (for instance, using XeF₂ etching for silicon) after deposition of high thermal conductivity materials 110. In one embodiment, the growth of high thermal conductivity material 110 (for instance, diamond) could be seeded by nanoparticles or microparticles of said high thermal conductivity material 110, where the deposition of the seed nanoparticles and microparticles could be performed using spin coating.

In one embodiment, an effective area of contact between bulk semiconductor 109 and high thermal conductivity material 110 exceeds 0.8 times that of a flat areal contact between a surface of an unpatterned bulk semiconductor and a surface of high thermal conductivity material 110.

Furthermore, FIG. 1C is a cross-section of cell 107 illustrating the tapered structures 112 of cell 107. In one embodiment, such tapered structures 112 cause thermal conductivity and/or thermal expansion in heat spreader 101 to gradually change from that of heat generating device 102 at one end of heat spreader 101 to that of the high-thermal conductivity material (e.g., high-thermal conductivity material 110) at the other end of heat spreader 101.

Referring to FIGS. 1A-1C, in one embodiment, heat spreader 101 is adjacent to a heat generating device 102, where device 102 can be an Integrated Circuit (IC), a System-in-Package (SiP), a 2.5D SiP, a 3D SiP, a single die, a group of die that are contiguous and/or continuous, and/or a group of die that are non-contiguous.

In one embodiment, heat spreader 101 is fabricated on the backside of heat generating device 102, or alternatively, attached to the backside of heat generating device 102 using hybrid bonding, fusion bonding, anodic bonding, covalent bonding, adhesive-based bonding, or other attachment methods that ensure an intimate gap-free bond between heat spreader 101 and heat generating device 102. In the embodiment in which fusion bonding (oxide-to-oxide) is utilized to attach heat spreader 101 and heat generating device 102 (see interface 103), the oxide films on the bonding surfaces of heat spreader 101 and/or heat generating device 102 have the following range of thicknesses: sub-2 nm, sub-4 nm, sub-10 nm, sub-50 nm, sub-100 nm, or sub-200 nm.

In one embodiment, heat spreader 101 performs the function of laterally spreading high heat flux in localized regions of heat-generating device 102 to prevent the temperature in the localized regions exceeding pre-determined limits. Exemplary local and average heat flux values for an exemplary heat generating device 102 are as follows: local (W/cm²)-sub-500, sub-1,000, sub-5,000, sub-10,000, sub-50,000, or sub-100,000; average (W/cm²): sub-100, sub-200, sub-500, sub-1,000, or sub-2,000.

In one embodiment, a lateral thermal conductivity of heat spreader 101 exceeds 200 W/mK, or 400 W/mK.

In one embodiment, an effective axial thermal conductivity of heat spreader 101 exceeds 10 W/mK, 50 W/mK, or 100 W/mK.

In one embodiment, interface 103 between heat-spreader 101 and heat generating device 102 does not contain any sub-Thermal Interface Materials (TIMs).

In one embodiment, heat spreader 101 is attached to heat sink 105 on the side of heat spreader 101 opposite to heat generating device 102. In one embodiment, the attachment is performed in a TIM-free manner. For example, hybrid bonding, fusion bonding, anodic bonding, covalent bonding, adhesive-based bonding, and/or other attachment methods that ensure an intimate gap-free bond between heat spreader 101 and heat sink 105 may be utilized. Alternatively, a TIM is utilized for such an attachment. Exemplary TIMs include polymer-derived ceramics, such as polymer-derived BN, specifically, polyborazylene-derived BN. In one embodiment, heat sink 105 is comprised metals (e.g., copper, aluminum) and/or bulk semiconductors (e.g., silicon, GaAs, etc.). In one embodiment, heat sink 105 contains heat-dissipation pathways that are micro-fabricated. These pathways may have coolant fluids running through them, which could be water, air, oil, or some other coolant. In one embodiment, heat sink 105 optionally contains machined structures (micro or macro-machined) to increase its lateral compliance (for instance). In one embodiment, heat sink 105 optionally has pin (micro-pin, nano-pin) structures that are used to interface with heat-spreader 101.

In one embodiment, the fabrication of heat spreaders 101 is performed either on a separate piece of bulk semiconducting substrate (e.g., silicon, which could optionally be lightly doped or undoped), or on heat generating device 102 itself. It is noted that fabrication on a separate piece of substrate has the advantage of higher thermal budgets during the fabrication of heat spreader 101, for instance, high-temperature (over-500° C.) deposition of high-thermal-conductivity materials, such as diamond, c-BN, carbon nanotube forests, etc. Additionally, fabrication on a separate piece of substrate allows heterogeneity between the device substrate and the heat spreader substrate. For instance, heat spreader 101 could be comprised of an electrically insulating substrate, such as lightly-doped or undoped silicon.

In one embodiment, the fabrication of heat spreader 101 involves one or more of the following process steps: (1) patterning, (2) etching, (3) coating/deposition, (4) planarization, and (5) thermal oxidation. Examples of patterning techniques include photolithography, nanoimprint lithography, electron-beam lithography, etc. Examples of etching techniques include deep etch techniques, plasma etching, metal assisted chemical etching (where the catalysts include Au, Pt, Pd, Ag, Ru, W, Cu, TiN, Ti, graphene, carbon, etc., and where the MACE could be liquid phase or vapor phase), crystallographic etching, wet etching, anisotropic vapor etching (e.g., vapor HF etching), etc. Examples of coating/deposition techniques include chemical vapor deposition (CVD), atomic layer deposition (ALD), physical vapor deposition (PVD) (e.g., e-beam deposition, sputtering, etc.), electrodeposition (of Cu, for instance), electroless deposition (of Cu, for instance), etc. An example of planarization includes chemical mechanical polishing.

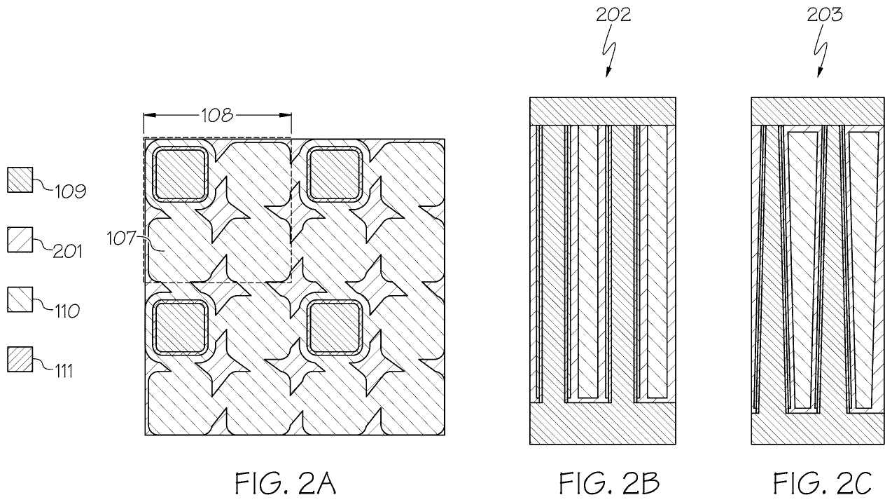

Referring now to FIG. 2A, FIG. 2A illustrates a top view of the unit cells (e.g., unit cells 107) of heat spreader 101 in a 2×2 array in accordance with an embodiment of the present disclosure.

As illustrated in FIG. 2A, heat spreader 101 is comprised of unit cells 107, where the lateral extent 108 of a unit cell 107 may have a lateral extent of sub-100 nm, sub-500 nm, sub-1 μm, sub-2 μm, sub-5 μm, sub-10 μm, sub-20 μm, sub-50 μm, sub-100 μm, sub-200 μm, or sub-500 μm.

In one embodiment, each cell 107 may be comprised of bulk semiconductor 109, such as silicon, an optional thin layer of thermally conductive compliant material 201 (e.g., carbon nanotube (CNT) forest, porous silicon, polymer-derived amorphous BN, other polymer-derived ceramics, air, etc.), high thermal conductivity material 110 (e.g., electroplated copper, b-BN (chemical vapor deposition (CVD) coated or anneal amorphous BN), or CVD diamond), and optional electrically-insulating material 111 (e.g., SiO₂, tantalum oxide/nitride). In one embodiment, the compliance of thermally conductive materials 201 is enabled by mechanical flexures made from thermally conductive material that are incorporated in the thermally conductive layer. The minimum feature size of said mechanical flexures could sub-500 nm, sub-200 nm, sub-100 nm, sub-50 nm, sub-20 nm, or sub-10 nm.

Furthermore, FIGS. 2B-2C illustrate a cross-section of unit cells 107 of FIG. 2A in accordance with an embodiment of the present disclosure.

As shown in FIGS. 2B-2C, there are two options for the cross-section of unit cells 107, namely, option 1 202 (FIG. 2B) and option 2 203 (FIG. 2C).

Referring to FIGS. 2A-2C, in conjunction with FIGS. 1A-1C, FIGS. 2A-2C illustrate the micro-architecture of heat spreader 101. In one embodiment, the topology of heat spreader 101 is optimally designed to maximize/minimize thermal resistance between device 102 and heat spreader 101 (for instance, to be below one of 0.2, 0.1, 005, 0.01 cm 2 K/W), lateral thermal conductivity (for instance, to be above one of 200, 400, 1000, 2000 W/mK), axial thermal conductivity (for instance, to be above one of 10, 50, 100, 200 W/mK), or minimize the mismatch in thermal expansion coefficients of heat spreader 101 and heat generating device 102 (for instance, to be below 0.1, 0.2, 0.5, 1, 2, 4, or 10 ppm).

In one embodiment, the cross-section of the structures in heat-spreader 101 is tapered to enhance phonon transport from hot-spots to the high-thermal-conductivity material in heat spreader 101. In one embodiment, the tapering is performed using RIE (reactive-ion etching), MACE (metal assisted chemical etching) with RIE to create taper, Ag-based MACE, etc.

In one embodiment, the structures in heat-spreader 101 are fabricated with an etch technique that creates smooth structure sidewalls (for instance, MACE). Low-sidewall-roughness structures can enable improved phonon transport and reduce interfacial thermal resistance.

In one embodiment, heat spreader 101 is designed with a goal of keeping the number of interfaces between disparate materials to be as low as possible.

In one embodiment, the process sequence used to fabricate heat spreader 101 could be optimized to limit the overall per-wafer cost of heat spreaders 101.

Additionally, the size, shape, and fabrication sequence for heat spreader 101 are designed so as to accommodate backside power rails, such as for electrical power delivery. For instance, the power rail lines could be located on the periphery on the backside of device 102; whereas, heat spreader 101 could be located in the rest of the backside area.

In one embodiment, heat spreader 101 and/or heat sink 105, are composed of composite materials, such as metal matrix composites (Cu—W, E-material (metal matrix composite consisting of beryllium matrix with beryllium oxide particles), dymalloy (metal matrix composite of 20% copper and 80% silver alloy matrix with type I diamond), AISIC (metal matrix composite consisting of aluminium matrix with silicon carbide particles), etc.), as well as SiC, etc.

As a result of the foregoing, the embodiments of the present disclosure provide a means for simplifying the design of heat spreaders and improving the performance of heat spreaders by eliminating the need for utilizing the thermal interface material.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A heat spreader placed in connection with a heat generating device, wherein said heat spreader comprises:
patterned regions with interspersed bulk semiconductor and thermally conductive material; and
tapered structures that cause thermal conductivity in said heat spreader to gradually change from that of said heat generating device to that of said thermally conductive material.

2. The heat spreader as recited in claim 1, wherein a lateral thermal conductivity of said heat spreader exceeds 400 W/mK.

3. The heat spreader as recited in claim 1, wherein an effective axial thermal conductivity of said heat spreader exceeds 100 W/mK.

4. The heat spreader as recited in claim 1, wherein an effective thermal expansion coefficient of said heat spreader matches a thermal expansion of said heat generating device.

5. The heat spreader as recited in claim 1, wherein said heat spreader comprises repeating unit cells.

6. The heat spreader as recited in claim 1, wherein said thermally conductive material comprises one of the following: copper, BN, boron phosphide, boron arsenide, aluminum nitride, and diamond.

7. The heat spreader as recited in claim 1, wherein said heat spreader is fabricated on a separate substrate compared to said heat generating device.

8. The heat spreader as recited in claim 7, wherein said heat spreader is attached to said heat generating device using one or more of the following; hybrid bonding, fusion bonding, anodic bonding, covalent bonding, and adhesive-based bonding.

9. The heat spreader as recited in claim 1, wherein an interface between said heat spreader and said heat generating device does not contain any thermal interface materials.

10. The heat spreader as recited in claim 1, wherein fabrication of said heat spreader involves one or more of the following: photolithography, nanoimprint lithography, electron-beam lithography, a deep etch technique, plasma etching, wet or vapor phase metal assisted chemical etching, crystallographic etching, wet etching, anisotropic vapor etching, chemical vapor deposition, atomic layer deposition, physical vapor deposition, electrodeposition, electroless deposition, a planarization technique, and chemical mechanical polishing.

11. A heat spreader placed in connection with a heat generating device, wherein said heat spreader comprises:
patterned regions with bulk semiconductor and thermally conductive material, wherein an effective area of contact between said bulk semiconductor and said thermally conductive material exceeds 0.8 times that of a flat areal contact between a surface of an unpatterned bulk semiconductor and a surface of said thermally conductive material, wherein an effective thermal expansion coefficient of said heat spreader matches a thermal expansion of said heat generating device.

12. The heat spreader as recited in claim 11, wherein a lateral thermal conductivity of said heat spreader exceeds 400 W/mK.

13. The heat spreader as recited in claim 11, wherein an effective axial thermal conductivity of said heat spreader exceeds 100 W/mK.

14. The heat spreader as recited in claim 11, wherein said heat spreader comprises repeating unit cells.

15. The heat spreader as recited in claim 11, wherein said thermally conductive material comprises one of the following: copper, BN, boron phosphide, boron arsenide, aluminum nitride, and diamond.

16. The heat spreader as recited in claim 11, wherein said heat spreader is fabricated on a separate substrate compared to said heat generating device.

17. The heat spreader as recited in claim 16, wherein said heat spreader is attached to said heat generating device using one or more of the following; hybrid bonding, fusion bonding, anodic bonding, covalent bonding, and adhesive-based bonding.

18. The heat spreader as recited in claim 11, wherein an interface between said heat spreader and said heat generating device does not contain any thermal interface materials.

19. The heat spreader as recited in claim 11, wherein fabrication of said heat spreader involves one or more of the following: photolithography, nanoimprint lithography, electron-beam lithography, a deep etch technique, plasma etching, wet or vapor phase metal assisted chemical etching, crystallographic etching, wet etching, anisotropic vapor etching, chemical vapor deposition, atomic layer deposition, physical vapor deposition, electrodeposition, electroless deposition, a planarization technique, and chemical mechanical polishing.
